(19) United States
(12) Patent Application Publication
(10) Pub. No.: US 2026/0168107 A1
(43) Pub. Date: Jun. 18, 2026

(54) MICRONEEDLE PRODUCTION METHOD INDEPENDENT OF PHOTOLITHOGRAPHY

(71) Applicant: BILKENT UNIVERSITESI ULUSAL NANOTEKNOLOJI ARASTIRMA MERKEZI, ANKARA (TR)

(72) Inventors: Ismail ES, ANKARA (TR); Abdullah KAFADENK, ANKARA (TR); Fatih INCI, ANKARA (TR)

(73) Assignee: BILKENT UNIVERSITESI ULUSAL NANOTEKNOLOJI ARASTIRMA MERKEZI, ANKARA (TR)

(21) Appl. No.: 19/123,553

(22) PCT Filed: Nov. 13, 2023
(86) PCT No.: PCT/TR2023/051315

§ 371 Date: Apr. 23, 2025

(30) Foreign Application Priority Data
Nov. 16, 2022 (TR) 2022/017275

(51) Int. Cl. C23C 28/00; C23C 14/18; C23C 14/22; C23C 16/34; C23C 16/505; C23C 16/56

(52) U.S. Cl. CPC C23C 28/34; C23C 14/18; C23C 14/221; C23C 16/345; C23C 16/505; C23C 16/56; C23C 28/322

(57) ABSTRACT

The present invention relates to a method (100) for producing microneedles rapidly as a result of processing geometries on a silicon plate by using a silicon substrate slicing and cutting machine (dicing saw) and dry abrasion technique.

### TECHNICAL FIELD

The present invention relates to a method for producing microneedles rapidly as a result of processing geometries on a silicon plate by using a silicon substrate slicing and cutting machine (dicing saw) and dry abrasion technique.

### BACKGROUND OF THE INVENTION

Before an orally administered drug reaches the bloodstream, its bioavailability decreases and the effect of the drug is substantially reduced. In addition, drugs are usually unstable and susceptible to the first pass effect in the gastrointestinal system. Given the multiple layers of skin, these drugs are delivered actively via a transdermal drug delivery (TDR) strategy by using hypodermic needles. These needles often cause pain. Although these needles are the gold standard, the microneedle-based active TDR strategy is a new technology wherein drug compounds are delivered into the bloodstream or directly into tumor tissue through micron-sized needles. These systems provide faster recovery at the injection site in comparison to hypodermic needles and they are widely preferred due to the fact that the molecules can be administered to the patient easily without causing pain. Such platforms are considered as one of the most popular of TDR methods and they are one of the latest active research areas currently since they revolutionize the concept of TDR. Microneedles can be used for different purposes based on their types. In their simplest form, microneedles enable to create microscopic holes by being applied to the skin and thus, different biomolecules enter the circulatory system by passing through these holes via diffusion. This technique is frequently used particularly in the pharmaceutical and cosmetic industry and it is used for determining the efficacy of drugs or creamy structures in the testing phase. As another type, hollow microneedles are frequently used. By means of holes located at the ends of the microneedles, the desired drugs can be delivered through the skin with the help of mechanical pumps. Finally, the microneedles produced can be moulded by using materials which have a polymeric structure and are completely soluble and a controlled release of the drugs included in thereof can be achieved through the skin.

To date, numerous microneedle-based platforms have been produced by using different materials, mostly silicon and metal, and drug delivery has been performed through various strategies. Techniques such as dry or wet abrasion, laser ablation, photolithography, wire erosion and 3D printing have been shown to be quite effective in designing these platforms. The production phase is more difficult due to the micro-structure geometric structures. The techniques used usually consist of multiple steps and the equipment used during their production is costly. Therefore, the development of techniques with low-cost, high-precision and shortened manufacturing process is of great importance for the economical production of microneedles.

The United States patent document no. WO2009021964, an application included in the state of the art, discloses microfabricated surgical devices and methods for producing them. The microneedle is made by deep reactive ion abrasion on a substrate surface. The needle tip, needle shaft, needle base and needle entry and exit ports are etched onto the substrate surface. The substrate may be silicon. The first coating, which may be silicon nitride (Si3N4), is deposited on the silicon by chemical vapour deposition method. A metallic layer such as chromium, gold or titanium is formed on the first coating and a second coating is made on thereof. following the coating, a silicon surface abrasion is performed in xenon difluoride etcher. Then, modelling is performed for microneedle is by photoresist lithography. The microfabricated needles obtained are used to inject pharmaceutical agents into humans or animals or to extract biological samples from them and limits injury or pain.

### SUMMARY OF THE INVENTION

An objective of the present invention is to realize a method for producing microneedles rapidly as a result of applying dry abrasion technique by opening channels of different geometries on the silicon substrate by using a silicon substrate slicing and cutting machine.

Another objective of the present invention is to realize a method for producing microneedles rapidly from geometries processed on a silicon plate by using only a silicon substrate slicing and cutting machine and then dry abrasion technique by eliminating the photolithography process which is also used in the fabrication of structures with very small sizes such as microneedle.

Another objective of the present invention is to realize a method for optimizing parameters such as speed of saw, thickness of saw, depth of cut and width of cut used in a technique wherein a cutting saw is used.

Another objective of the present invention is to realize a method for optimizing process steps of a dry etching process with xenon fluoride gas which is used in production processes of microneedles consisting of geometries produced by using silicon substrate slicing and cutting machine.

Another objective of the present invention to realize a method for reducing production time by means of process optimization and for producing microneedles with a pyramidal structure and desired sizes.

Another objective of the present invention to realize a method for increasing the mechanical strengths of produced microneedles by coating biocompatible materials on thereof and for improving their surface roughness properties.

### DETAILED DESCRIPTION OF THE INVENTION

“A Microneedle Production Method Independent of Photolithography” realized to fulfil the objectives of the present invention is shown in the figures attached, in which:

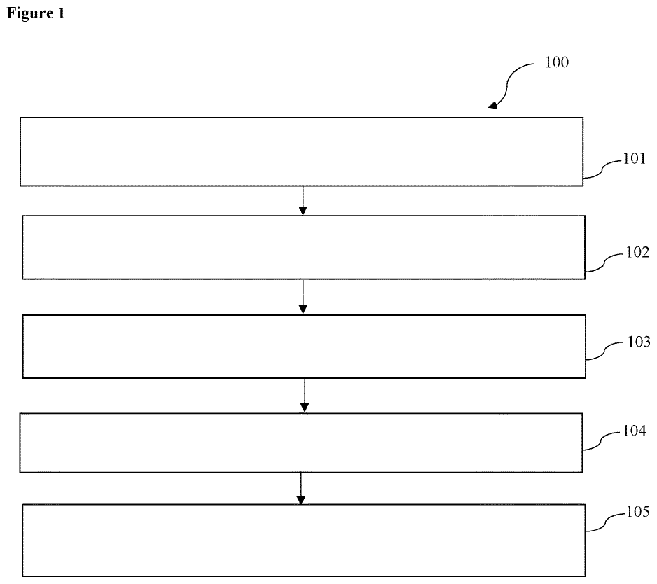

FIG. 1 is a flow chart of the inventive method.

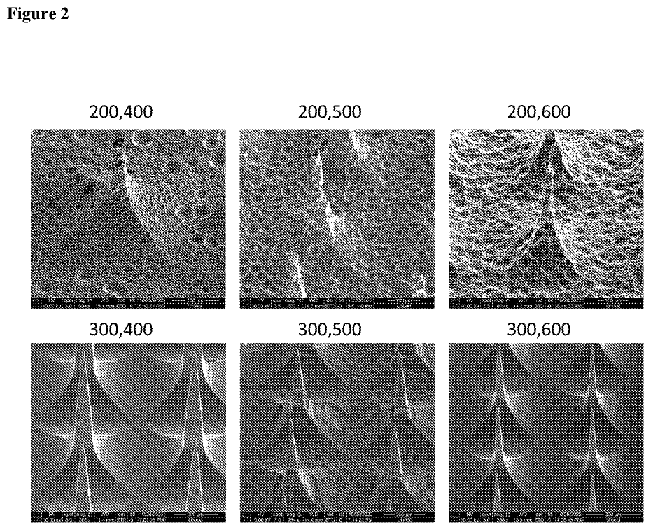

FIG. 2 is the photos of microneedles, which are produced at the specified parameters (depth, distance (200, 400), (200, 500), (200, 600), (300, 400), (300, 500), (300, 600)), taken under a scanning electron microscope.

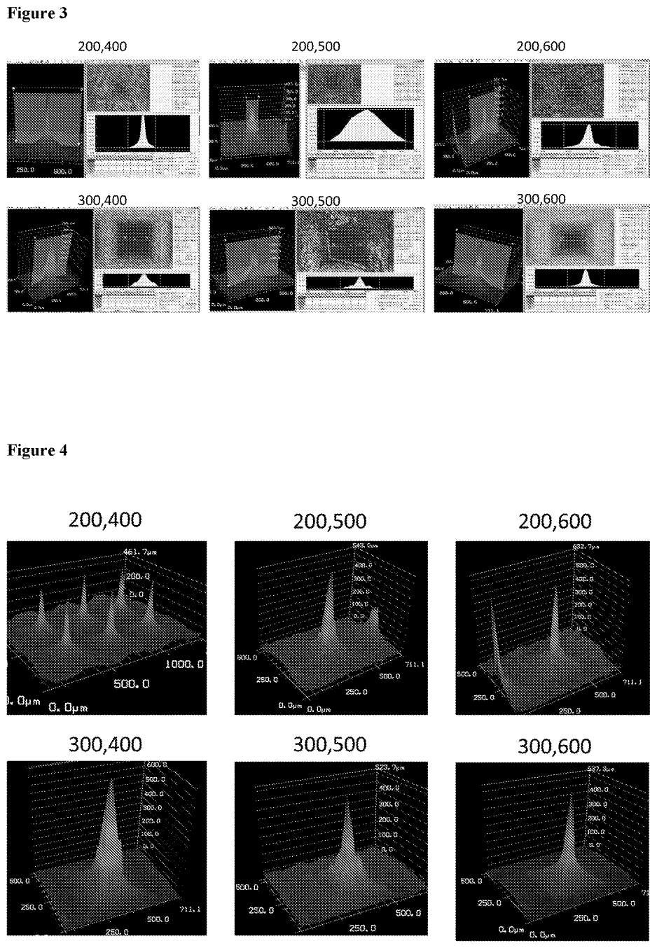

FIG. 3 is the height values measured under a 3D scanning laser microscope of microneedles produced at the specified parameters.

FIG. 4 is the 3D structural views of microneedles, which are produced at the specified parameters, taken under a 3D scanning laser microscope.

FIG. 5 is the average lengths of microneedles, which are produced at the specified parameters.

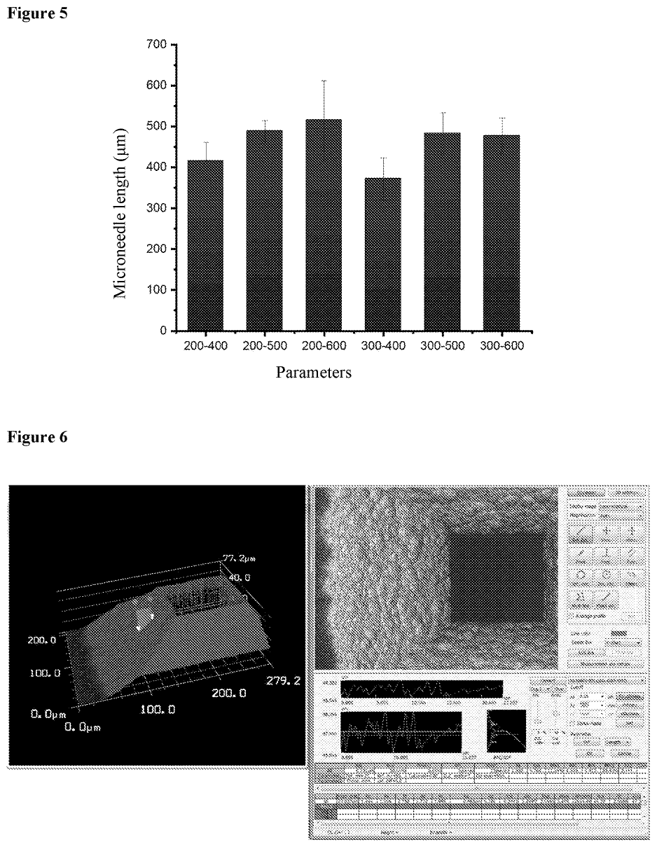

FIG. 6 is the roughness values of the microneedles.

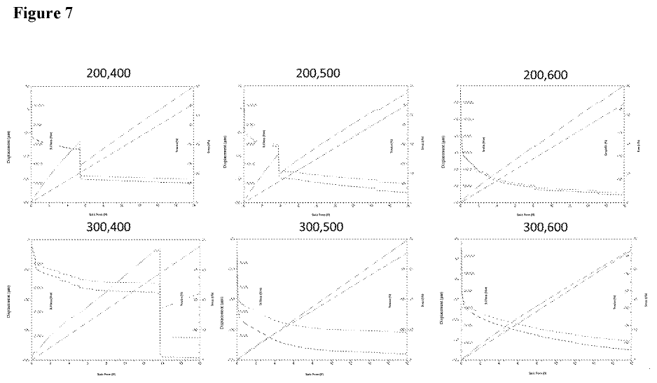

FIG. 7 is the graphs showing the measurement of dynamic mechanical analysis of the microneedles which are produced at the specified parameters.

The components illustrated in the figures are individually numbered, where the numbers refer to the following:
100. Method

The inventive method (100) for producing microneedles rapidly as a result of processing geometries on a silicon plate by using a silicon substrate slicing and cutting machine and dry abrasion technique comprises the steps of
cutting a silicon plate into desired sizes by using a silicon substrate slicing and cutting machine (101);
coating both cut surfaces of silicon plates which are cut into desired sizes (102);
processing of geometric parameters for microneedle formation on each silicon plate cut (103);
subjecting the silicon plate, which is processed with geometric parameter, to dry abrasion (104);
coating the microneedles, which are obtained after dry abrasion, in order to increase their strength and reduce surface roughness (105).

In the step of cutting a silicon plate into desired sizes by using a silicon substrate slicing and cutting machine (101) of the inventive method (100); a silicon plate is preferably cut into squares of 0.1-5 cm² by using a silicon substrate slicing and cutting machine.

In the step of coating both cut surfaces of silicon plates which are cut into desired sizes (102) of the inventive method (100); coating is performed with silicon nitride (Si₃N₄). In another embodiment of the invention, coating is performed with xenon difluoride non-selective materials. Both surfaces of 1-10 inch silicon parts with a thickness of 500-1000 μm are coated by using plasma enhanced chemical vapor deposition (PECVD) technique. The coating thickness is determined as 100-1000 nm in the coating performed. The coating is performed at 50-500° C. with 100-1000 mTorr chamber pressure at 20-500 W RF power. The nitrogen gas pressure used during coating is determined as 50-500 m Torr and the silane content in thereof is determined as 1-5% (v/v). NH₃ pressure is fixed at 10-100 m Torr.

In the step of processing of geometric parameters for microneedle formation on each silicon plate cut (103) of the inventive method (100); each silicon plate cut into the desired sizes is placed into the silicon substrate slicing and cutting machine again and the parameters required for microneedle production such as the entry height of the blade into the silicon plate, the speed and the edge length of the square structures wherein microneedles will be formed, are determined and then processed on the silicon plate. The distance of 10-500 μm, which is planned to be between the microneedles, is adjusted by changing the diameter of the blade of the silicon substrate slicing and cutting machine. Preferred parameters are given in the Table 1. In one embodiment of the invention, instead of a silicon substrate slicing and cutting machine, techniques performing micro-milling or precision abrasion are used to cut channels on the coated silicon parts.

TABLE 1
Geometric parameters processed by silicon substrate slicing and cutting
machine on a silicon plate for the formation of microneedles

| | SIDE LENGTH OF | DEPTH |
|---|---|---|
| SILICON | THE SQUARE | PENETRATED |
| PLATE | STRUCTURES TO BE | WITH A KNIFE |
| THICKNESS | FORMED IN THE | ON SILICON |
| (μM) | MICRONEEDLE (μM) | PLATE SS(μM) |
| 1000 | 200 | 400 |
| | | 500 |
| | | 600 |
| | 300 | 400 |
| | | 500 |
| | | 600 |

In the step of subjecting the silicon plate, which is processed with geometric parameter, to dry abrasion (104) of the inventive method (100); the silicon plate-on the surface of which geometric processing is made in accordance with the desired parameters—is subjected to a dry abrasion process by using xenon fluoride (XeF₂) gas and a microneedle is obtained after the abrasion. The xenon fluoride gas pressure used for dry abrasion is selected as 1-5 m Torr and the abrasion time is selected as 30-600 s. In one embodiment of the invention, the abrasion process to be performed on the silicon plate can be carried out by using dry or wet abrasion techniques or laser engraving techniques instead of xenon fluoride. Depending on the abrasion technique to be applied to the silicon plate, glass or polymeric material may be preferred for the abrasion process.

In the step of coating the microneedles, which are obtained after dry abrasion, in order to increase their strength and reduce surface roughness (105) of the inventive method (100); coating is performed by titanium or biocompatible metals on the surface where abrasion is made in order to increase the strength of the dry-etched microneedles against mechanical stress. In order to further increase the mechanical strength of the dry-etched microneedles, an ultra-hard coating method is used in the form of an ion beam evaporator.

The microneedles obtained by the inventive method (100) are characterized. The microneedles were examined under a light microscope at first immediately after the dry abrasion process. The abrasion process was terminated right after it was determined that the microneedles had reached the desired shape. Surface properties of the microneedles such as morphology and roughness, which were determined to be free of any residual silicon nitrate, were determined by nano-scanning electron microscopy and 3D laser scanning microscopy (Keyence vk x100). The height and width of the microneedles were also determined by using these microscopes. It is determined by EDX analysis whether the microneedles were coated with titanium to increase their mechanical strength. The data showing the changes in surface roughness properties after coating are given in the Table 2.

TABLE 2
Change of surface roughness properties after coating

| | Ra (μm) | Rz (μm) | Rq (μm) |
|---|---|---|---|
| Microneedles with | 0.71 | 4.671 | 0.888 |
| uncoated surface (Silicon) | | | |
| Titanium coated | 0.46 | 2.75 | 0.586 |
| microneedles | | | |

*Ra is called as the arithmetic mean roughness;
**Rq is called as the root-mean-square roughness;
***Rz is called as the mean value of the absolute values of the heights of the five highest profile peaks and the depths of the five deepest valleys within the assessment length.

With the inventive method (100), a photolithography method—which is a laborious, time-consuming and expensive method for microneedle production—is eliminated and instead of this, a silicon plate—which is more practical and does not require a clean space—is cut with a saw to the desired depth and width and exposed to dry abrasion. Thereby, microneedle production is accelerated and thousands of microneedles can be produced in a very short time.

Within these basic concepts; it is possible to develop various embodiments of the inventive “Microneedle Production Method (100) Independent of Photolithography”; the invention cannot be limited to examples disclosed herein and it is essentially according to claims.

1. A method (100) for producing microneedles rapidly as a result of processing geometries on a silicon plate by using a silicon substrate slicing and cutting machine and dry abrasion technique; characterized by the steps of cutting a silicon plate into desired sizes by using a silicon substrate slicing and cutting machine (101);
coating both cut surfaces of silicon plates which are cut into desired sizes (102);
processing of geometric parameters for microneedle formation on each silicon plate cut (103);
subjecting the silicon plate, which is processed with geometric parameter, to dry abrasion (104);
coating the microneedles, which are obtained after dry abrasion, in order to increase their strength and reduce surface roughness (105).

2. A method (100) according to claim 1; characterized in that in the step of cutting a silicon plate into desired sizes by using a silicon substrate slicing and cutting machine (101); a silicon plate is cut into squares of 0.1-5 cm2 by using a silicon substrate slicing and cutting machine.

3. A method (100) according to claim 1; characterized in that in the step of coating both cut surfaces of silicon plates which are cut into desired sizes (102); coating is performed with silicon nitride (Si3N4).

4. A method (100) according to claim 1; characterized in that in the step of coating both cut surfaces of silicon plates which are cut into desired sizes (102); coating is performed with xenon difluoride non-selective materials.

5. A method (100) according to claim 3; characterized in that in the step of coating both cut surfaces of silicon plates which are cut into desired sizes (102); both surfaces of 1-10 inch silicon parts with a thickness of 500-1000 μm are coated by using plasma enhanced chemical vapor deposition technique.

6. A method (100) according to claim 3; characterized in that in the step of coating both cut surfaces of silicon plates which are cut into desired sizes (102); the coating thickness is determined as 100-1000 nm in the coating performed and the coating is performed at 50-500° C. with 100-1000 mTorr chamber pressure at 20-500 W RF power; the nitrogen gas pressure used during coating is determined as 50-500 m Torr and the silane content in thereof is determined as 1-5% (v/v); and the NH3 pressure is fixed at 10-100 m Torr.

7. A method (100) according to claim 1; characterized in that in the step of processing of geometric parameters for microneedle formation on each silicon plate cut (103); each silicon plate cut into the desired sizes is placed into the silicon substrate slicing and cutting machine again and the parameters required for microneedle production such as the entry height of the blade into the silicon plate, the speed and the edge length of the square structures wherein microneedles will be formed, are determined and then processed on the silicon plate.

8. A method (100) according to claim 7; characterized in that in the step of processing of geometric parameters for microneedle formation on each silicon plate cut (103); the distance of 10-500 μm, which is planned to be between the microneedles, is adjusted by changing the diameter of the blade of the silicon substrate slicing and cutting machine.

9. A method (100) according to claim 7; characterized in that in the step of processing of geometric parameters for microneedle formation on each silicon plate cut (103); instead of a silicon substrate slicing and cutting machine, techniques performing micro-milling or precision abrasion are used to cut channels on the coated silicon parts.

10. A method (100) according to claim 1; characterized in that in the step of subjecting the silicon plate, which is processed with geometric parameter, to dry abrasion (104); the silicon plate—on the surface of which geometric processing is made in accordance with the desired parameters—is subjected to a dry abrasion process by using xenon fluoride (XeF2) gas and a microneedle is obtained after the abrasion.

11. A method (100) according to claim 10; characterized in that in the step of subjecting the silicon plate, which is processed with geometric parameter, to dry abrasion (104); the xenon fluoride gas pressure used for dry abrasion is selected as 1-5 m Torr and the abrasion time is selected as 30-600 s.

12. A method (100) according to claim 10; characterized in that in the step of subjecting the silicon plate, which is processed with geometric parameter, to dry abrasion (104); the abrasion process to be performed on the silicon plate is carried out by using dry or wet abrasion techniques or laser engraving techniques instead of xenon fluoride.

13. A method (100) according to claim 10; characterized in that in the step of subjecting the silicon plate, which is processed with geometric parameter, to dry abrasion (104); depending on the abrasion technique to be applied to the silicon plate, glass or polymeric material is preferred for the abrasion process.

14. A method (100) according to claim 1; characterized in that in the step of coating the microneedles, which are obtained after dry abrasion, in order to increase their strength and reduce surface roughness (105); coating is performed by titanium or biocompatible metals on the surface where abrasion is made in order to increase the strength of the dry-etched microneedles against mechanical stress.

15. A method (100) according to claim 14; characterized in that in the step of coating the microneedles, which are obtained after dry abrasion, in order to increase their strength and reduce surface roughness (105); in order to further increase the mechanical strength of the dry-etched microneedles, an ultra-hard coating method is used in the form of an ion beam evaporator.
